(19) United States
(12) Patent Application Publication
(10) Pub. No.: US 2021/0225681 A1
(43) Pub. Date: Jul. 22, 2021

(54) VACUUM PROCESSING APPARATUS

(71) Applicant: ULVAC, INC., Kanagawa (JP)

(72) Inventor: Yoshinori Fujii, Kanagawa (JP)

(73) Assignee: ULVAC, INC., Kanagawa (JP)

(21) Appl. No.: 16/645,611

(22) PCT Filed: Jul. 23, 2019
(86) PCT No.: PCT/JP2019/028814

§ 371 Date: Mar. 9, 2020

(30) Foreign Application Priority Data
Oct. 30, 2018 (JP) 2018-204437

(51) Int. Cl. H01L 21/683; C23C 14/34; C23C 14/50; C23C 14/54

(52) U.S. Cl. CPC H01L 21/6833; C23C 14/541; C23C 14/50; C23C 14/34

(57) ABSTRACT

The vacuum processing apparatus of this invention has: a vacuum chamber capable of forming vacuum atmosphere; and a stage for supporting inside the vacuum chamber a to-be-processed substrate. The stage has: a base to be selectively cooled; a chuck plate disposed on the base so as to electrostatically absorb the to-be-processed substrate; and a hot plate interposed between the base and the chuck plate, whereby the to-be-processed substrate electrostatically absorbed to the surface of the chuck plate is controlled to a predetermined temperature above the room temperature. The vacuum processing apparatus further has: a thermal insulation plate, disposed between the base and the hot plate, for restraining thermal transmission from the hot plate to the base. A high-emissivity layer having a higher emissivity than an upper surface of the base is disposed between the base and the thermal insulation plate.

### TECHNICAL FIELD

The present invention relates to a vacuum processing apparatus provided with: a vacuum chamber which is capable of forming therein a vacuum atmosphere; and a stage for supporting inside the vacuum chamber a substrate to be processed (a to-be-processed substrate).

### BACKGROUND ART

In the steps of manufacturing, e.g., a semiconductor device, there is a step for carrying out vacuum processing such as film-forming processing, etching processing and the like on a to-be-processed substrate such as a silicon wafer and the like. As apparatuses to be used in this kind of vacuum processing, there is known one, e.g., in patent document 1, which is provided with: a vacuum chamber in which vacuum atmosphere can be formed; and a stage for supporting the to-be-processed substrate inside the vacuum chamber. In this apparatus in order for the to-be-processed substrate to be controlled to a predetermined temperature (e.g., 300° C.) above a room temperature during the vacuum processing, the stage has: a base to be selectively cooled; a chuck plate which is mounted on the base and which electrostatically absorbs the to-be-processed substrate; and a hot plate which is interposed between the base and the chuck plate (the chuck plate and the hot plate may be integrally formed). Further, in this arrangement, in order to efficiently heat the to-be-processed substrate by the hot plate, there is further provided, between the base and the hot plate, a thermal insulation plate made of an insulating material so that the heat transmission (heat sink) from the hot plate to the base is restrained.

By the way, among the above-mentioned vacuum processing apparatuses, there is one like, e.g., a sputtering apparatus in which plasma is caused to be generated inside the vacuum chamber, and sputtered particles generated by sputtering of a target are made to get adhered and deposited, thereby carrying out the film-forming processing. At this time, the to-be-processed substrate is subjected to heat input other than from the hot plate, the heat input being due to the energy of plasma and the energy owned by the sputtered particles that are incident on the to-be-processed substrate. Then, even though the to-be-processed substrate is controlled, during the vacuum processing, to the predetermined temperature (e.g., 300° C.) that is above the room temperature, there are cases where the to-be-processed substrate gets heated above this control temperature. This phenomenon has the possibility of giving adverse effect on the quality and the like of the thin films to be formed.

Therefore, in order to lower the temperature of the hot plate as soon as ever possible should the to-be-processed substrate be heated above the control temperature, it is necessary to stop or reduce the energizing current to the hot plate and also to cause heat sink to take place from the hot plate to the cooled base. However, if the thermal insulation plate is present between the hot plate and the base as in the prior art example, the thermal transfer between the hot plate and the base by radiation will become dominant. As a result, heat rays (e.g., infrared rays below 4 μm in wave length) to be emitted from the hot plate will permeate through the thermal insulation plate for consequent reflection on the upper surface of the base, and the reflected heat rays will return again to the hot plate. Therefore, there is a problem in that, even through the energizing current to the hot plate is stopped or reduced, the hot plate temperature will not be lowered soon enough.

### PRIOR ART DOCUMENTS

### Patent Documents

Patent Document 1: JP-T-2018-518833

### SUMMARY OF THE INVENTION

### Problems that the Invention is to Solve

In view of the above-mentioned points, this invention has an object of providing a vacuum processing apparatus which is arranged to be able to control the to-be-processed substrate to a predetermined temperature even in case where there is a heat input to the to-be-processed substrate from other than the hot plate during vacuum processing.

### Means for Solving the Problems

In order to solve the above-mentioned problem, this invention is a vacuum processing apparatus comprising: a vacuum chamber capable of forming vacuum atmosphere; a stage for supporting inside the vacuum chamber a to-be-processed substrate. The stage has: a base to be selectively cooled; a chuck plate disposed on the base so as to electrostatically absorb the to-be-processed substrate; and a hot plate interposed between the base and the chuck plate, whereby the to-be-processed substrate electrostatically absorbed to a surface of the chuck plate is controlled to a predetermined temperature above a room temperature. The vacuum processing apparatus further comprises a thermal insulation plate, disposed between the base and the hot plate, for restraining thermal transmission from the hot plate to the base. A high-emissivity layer having a higher emissivity than an upper surface of the base is disposed between the base and the thermal insulation plate.

According to this invention, since the high-emissivity layer is disposed between the base and the thermal insulation plate, the heat rays to be emitted from the hot plate are absorbed by the high-emissivity layer and are transmitted to the base. Therefore, by stopping or lowering the energizing current to the hot plate, the hot plate temperature can be lowered at an early time. Accordingly, even in case there is a heat input to the to-be-processed substrate from other than the hot plate during vacuum processing, the to-be-processed substrate can be controlled to the predetermined temperature.

In this invention, it is more preferable that the emissivity of the high-emissivity layer relative to the heat rays (infrared rays) below wave length below 4 μm is above 0.49. If this range is deviated, there will be a disadvantage in that the heat rays emitted from the to-be-processed substrate cannot be efficiently absorbed. In this case, if the above-mentioned high-emissivity layer is composed of a film given by AlₓTi₁₋ₓN (0.1≤x≤0.95), the emissivity of the high-emissivity layer can surely be made above 0.49.

By the way, it is known that the amount of heat-ray emission from an outer peripheral part of the hot plate is larger than that from the central part thereof. If the high-emissivity layer is formed so as to cover the entire surface of the upper surface of the base, the temperature in the outer peripheral part of the hot plate becomes lower than that in the central part thereof. As a result, a temperature difference between the central part and the outer peripheral part of the hot plate is likely to occur. As a solution, in this invention, by forming the high-emissivity layer in a manner to cover such a part on the upper surface of the base as is exclusive of an outer peripheral part of the upper surface, the difference in temperature between the central part and the outer peripheral part of the hot plate can advantageously be restrained from occurring.

### BRIEF DESCRIPTION OF THE DRAWINGS

FIG. 1 is a schematic sectional view to show the sputtering apparatus according to an embodiment of this invention.

FIG. 2 is a sectional view showing by enlarging a part of FIG. 1.

FIG. 3 is a sectional view to show a modified embodiment of this invention.

### MODES FOR CARRYING OUT THE INVENTION

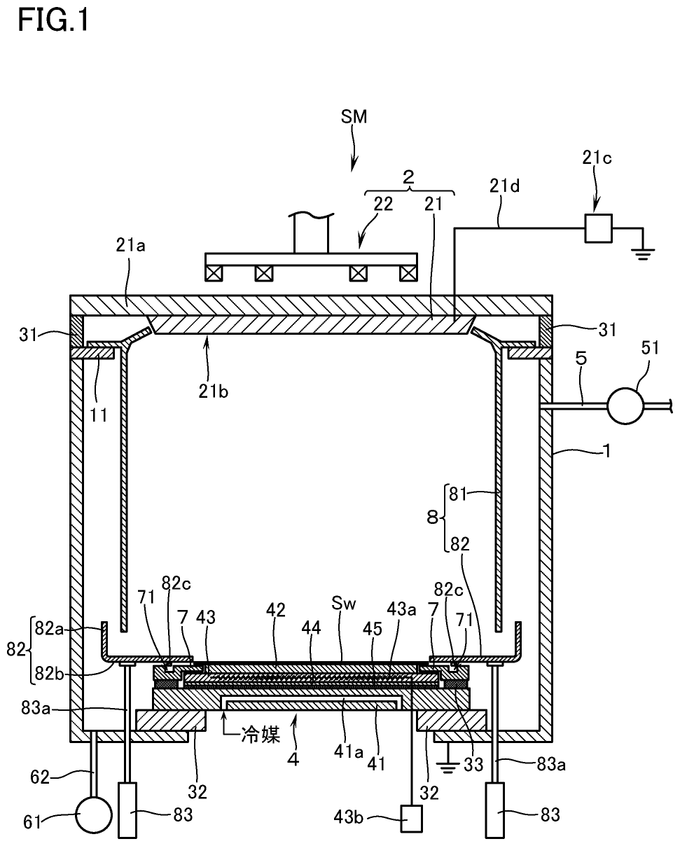

With reference to the drawings, a description will now be made of an embodiment of a vacuum processing apparatus according to this invention in which a vacuum processing apparatus is defined to be a magnetron type of sputtering apparatus, and a to-be-processed substrate is defined to be a silicon wafer (hereinafter referred to as a “substrate Sw”), and in which a predetermined thin film is formed on the surface of the substrate Sw. In the following description, the terms denoting the direction such as “upper” and “lower” shall be understood to be based on a posture of installation of the sputtering apparatus as the vacuum processing apparatus as shown in FIG. 1.

With reference to FIG. 1, reference mark SM denotes a sputtering apparatus of this embodiment. The sputtering apparatus SM is provided with a vacuum chamber 1 which is capable of forming a vacuum atmosphere. The vacuum chamber 1 has detachably mounted, on an upper opening thereof, a cathode unit 2. The cathode unit 2 is constituted by a target 21, and a magnet unit 22 to be disposed above the target 21. As the target 21, known ones such as those made of aluminum, copper, titanium, aluminum oxide and the like are utilized depending on the thin film to be formed on the surface of the substrate Sw. The target 21 is mounted on an upper part of the vacuum chamber 1, in a state of being connected to a backing plate 21a, through an electrical insulating body 11 that is mounted on an upper wall of the vacuum chamber 1, the target 21 being mounted in a posture in which the sputtering surface (surface to be sputtered) 21b looks downward.

The target 21 has connected thereto an output 21d from a sputtering power supply 21c which is constituted by DC power supply, AC power supply and the like, depending on the kind of target. It is thus so arranged that, depending on the kind of target, predetermined power, e.g., with negative potential or high frequency power of predetermined frequency can be supplied to the target 21. The magnet unit 22 has a known construction of closed magnetic field or cusp magnetic field in which: a magnetic field is generated in the space below the sputtering surface 21b of the target 21; electrons and the like ionized below the sputtering surface 21b at the time of sputtering are collected; and the sputtered particles that have been scattered from the target 21 are efficiently ionized. Therefore, detailed description thereof is omitted here.

At the bottom part of the vacuum chamber 1, there is disposed a stage 4 in a manner to face the target 21. The stage 4 has: a base 41 which is made into a cylindrical profile of metal (e.g., made of stainless steel, SUS) and is mounted through an insulating body 32 provided at a bottom part of the vacuum chamber 1; and a chuck plate 42 which is mounted on the base 41. The base 41 has formed therein coolant circulation passages 41a for circulating a coolant to be supplied from a chiller unit (not illustrated) so that selective cooling can be made. The chuck plate 42 has an outside diameter that is slightly smaller than the upper surface of the base 41, and has built therein an electrode for an electrostatic chuck. It is so arranged that, when voltage is applied from a chuck power supply (not illustrated) for the electrostatic chuck to this electrode, the substrate Sw is electrostatically absorbed to the upper surface of the chuck plate 42. Further, between the base 41 and the chuck plate 42 there is interposed a hot plate 43 made, e.g., of aluminum nitride. This hot plate 43 has built therein a heating means 43a such as a heater and the like. It is thus so arranged that, by energizing this heating means 43a from the power supply 43b, the hot plate 43 can be heated to a predetermined temperature (e.g., 300° C. to 500° C.) depending on the charged current. An arrangement is thus so made that the substrate Sw can be controlled to a predetermined temperature (e.g., 350° C.) above the room temperature by heating with the hot plate 43 and by cooling of the base 41 by circulating the coolant. Here, in order to restrain the heat transmission from the hot plate 43 that is heated to the base 41 that is cooled, there is provided, between the base 41 and the hot plate 43, a thermal insulation plate 44 which is made of an insulating material such as quartz, sapphire, and the like and which is made to coincide with the profile of the upper surface of the hot plate 43.

The side wall of the vacuum chamber 1 has connected threreto a gas pipe 5 for introducing sputtering gas, and the gas pipe 5 is in communication with a gas source (not illustrated) through a mass flow controller 51. As the sputtering gas there are included not only rare gases such as argon gas and the like which is introduced into the vacuum chamber 1 at the time of forming plasma, but also reactant gases such as oxygen gas, nitrogen gas and the like. The lower wall of the vacuum chamber 1 has connected thereto an exhaust pipe 62 which is in communication with a vacuum pump 61 which is constituted by a turbo molecular pump, a rotary pump, and the like. It is thus so arranged that the vacuum chamber 1 can be evacuated and, at the time of sputtering, the vacuum chamber 1 can be maintained at a predetermined pressure in a state in which the sputtering gas has been introduced therein.

Around the stage 4 in the vacuum chamber 1, there are provided platen rings 7 at a distance from one another such that the platen rings 7 serve the function of an adhesion preventive plate, as a result of covering the outer peripheral part 43c on an upper surface of the hot plate 43, thereby preventing the sputtered particles generated by sputtering of the target 21 from depositing on the outer peripheral part 43c on the upper surface of the hot plate 43. The platen rings 7 are made of a known material such as aluminum oxide, stainless steel and the like, and are disposed on an outer peripheral part of the upper surface of the base 41 through an insulating body 33. Further, inside the vacuum chamber 1 there is provided an adhesion preventive plate 8 for preventing the sputtered particles from depositing on the inner wall surface of the vacuum chamber 1. The adhesion preventive plate 8 is made up of an upper adhesion preventive plate 81 and a lower adhesion preventive plate 82, each being made of known material such as aluminum oxide, stainless steel and the like. The upper adhesion preventive plate 81 has a cylindrical profile and is suspended through an engaging part 11 disposed on an upper part of the vacuum chamber 1. The lower adhesion preventive plate 82 has also a cylindrical profile and, at radial outside free end thereof, has formed therein an erected wall part 82a that is erected upward. The lower adhesion preventive plate 82 has connected thereto driving shafts 83a from driving means 83 such as motors, air cylinders and the like, the driving shafts extending by penetrating through the lower wall of the vacuum chamber 1. By the driving means 83 the lower adhesion preventive plate 82 is moved up or down between a film-forming position in which the film formation by sputtering is carried out and a transfer position which is higher than the film-forming position and in which the transfer of the substrate Sw to and from the stage 4 is carried out by a vacuum robot (not illustrated). It is so designed that, at the film-forming position of the lower adhesion preventive plate 82, the lower end part of the upper adhesion preventive plate 81 and the upper end part of the erected wall part 82a are overlapped with each other in the up-and-down direction.

Those flat parts 82b of the lower adhesion preventive plate 82 which extend at right angles to the vertical direction are so dimentioned that the diametrically inward parts lie opposite to the platen rings 7. At a predetermined position on the lower surface of the flat parts 82b, there is formed, e.g., an annular projection 82c. At a position on the upper surface of the platen rings 7, there are formed an annular recessed groove 71 in a manner to correspond to the projection 82c. At the film-forming position, a so-called labyrinth seal is formed by the projection 82c of the flat part 82b and the recessed groove 71 of the platen rings 7. It is thus so arranged that the sputtered particles can be prevented from getting wrapped around into that space inside the vacuum chamber 1 that is positioned below the lower adhesion preventive plate 82 around the substrate Sw. Further, the sputtering apparatus SM is provided with a control means (not illustrated) of a known construction including a microcomputer, a storage element, a sequencer and the like. This control means performs an overall control of each of the parts, at the time of sputtering, such as sputtering power supply 21c, power supply 43b, massflow controller 51, vacuum pump 61 and the like. In addition, in case the temperature of the hot plate 43 is lowered, the control means performs a control of stopping or lowering the energizing current from the power supply 43b to the heating means 43a. Description will hereinbelow be made of a film forming method by citing an example in which, on condition that the target 21 is an aluminum, an aluminum film is formed by the above-mentioned sputtering apparatus SM on the surface of the substrate Sw.

After having evacuated the vacuum chamber 1 by operating the vacuum pump 61, at the transfer position of the lower adhesion preventive plate 82, the substrate Sw is transferred by the vacuum transfer robot (not illustrated) onto the stage 4. The substrate Sw is thus mounted on the upper surface of the chuck plate 42 on the stage 4. Once the vacuum transfer robot has been withdrawn, the lower adhesion preventive plate 82 is moved to the film-forming position and, at the same time, predetermined voltage is applied from the power supply (not illustrated) to the electrode of the chuck plate 42. The substrate Sw is thus electrostatically adhered to the upper surface of the chuck plate 42. Accompanied by this operation, the hot plate 43 is heated by energizing from the power supply 43b to the heater 43a of the hot plate 43 and, at the same time, the base 41 is cooled by circulating the coolant to the coolant circulation passage 41a. Once the temperature of the substrate Sw has reached the predetermined temperature (e.g., 350° C.) above the room temperature, argon gas as the sputtering gas is introduced at a predetermined flow rate (the pressure inside the vacuum chamber 1 at this time is 0.5 Pa). Accompanied by this operation, the target 21 is charged with predetermined power (e.g., 3 kW to 50 kW) with negative potential from the sputtering power supply 21c. According to these operations, plasma is formed inside the vacuum chamber 1 so that the sputtering surface 21b of the target 21 gets sputtered by the ions of the argon gas in the plasma. The sputtered particles from the target 21 will then get adhered to, and deposited on, the substrate Sw, thereby forming an aluminum film.

Here, as described above, the substrate Sw will be subject to the heat input other than from the hot plate 43 due to the plasma and the energy owned by the sputtered particles that are incident into the substrate Sw. Even though the substrate Sw is being controlled at a predetermined temperature (e.g., 350° C.) during the film formation, there are cases where the substrate Sw gets heated above (e.g., 390° C.) this control temperature. In this case, the charged electric current from the power supply 43b to the hot plate 43 must be stopped or reduced and, at the same time, heat sink must be caused to take place from the hot plate 43 to the base 41. However, due to the presence of the insulating plate 44, the thermal transfer between the hot plate 43 and the base 41 will be predominantly due to radiation. The temperature of the hot plate 43 will thus be not lowered soon enough.

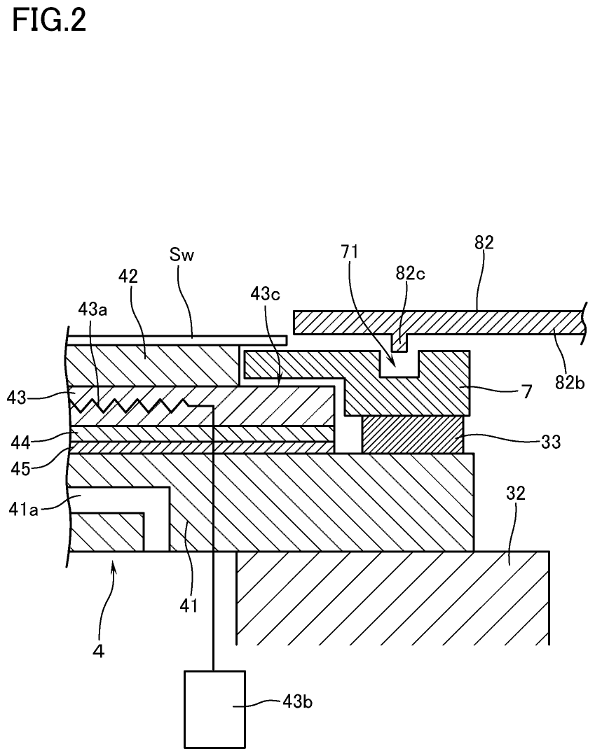

Therefore, in this embodiment, with reference also to FIG. 2, a high-emissivity layer 45 having a higher emissivity than the upper surface of the base 41 is disposed between the base 41 and the insulating plate 44 so that the radiation cooling effect of the hot plate 43 can be increased. This high-emissivity layer 45 is composed, e.g., of an AlₓTi₁₋ₓN film (0.1≤x≤0.95) so as to have a high emissivity of above 0.49 relative to the heat rays (infrared ray) below wavelength, e.g., of 4 μm. Since the AlₓTi₁₋ₓN film has little emission gas when heat rays are absorbed, it can advantageously be used as a high-emissivity layer 45. By the way, in case the high-emissivity layer 45 is composed, e.g., of an AlₓTi₁₋ₓN film (0.8≤x≤0.95), the emissivity of the high-emissivity layer 45 can be made more preferably above 0.6. The high-emissivity layer 45 may be formed on the upper surface of the base 41 or on the lower surface of the thermal insulation plate 44 but, by forming the high-emissivity layer on the upper surface of the base 41 than on the lower surface of the thermal insulation plate 44, the heat rays that have been absorbed by the high-emissivity layer 45 can be more efficiently transmitted to the base 41. As a method of forming the high-emissivity layer 45, there may be used a known method such as a sputtering method, a vacuum evaporation method and the like and, therefore, no detailed description will be made here.

According to the above embodiment, since there has been provided a high-emissivity layer 45 between the base 41 and the thermal insulation plate 44, the heat rays to be emitted from the hot plate 43 can be absorbed by the high-emissivity layer 45, and the absorbed heat can be transmitted to the base 41. In other words, due to the high-emissivity layer 45, the radiation cooling effect of the hot plate 43 can be enhanced so that heat sink can be made to take place from the hot plate 43 to the base 41. Therefore, if the energized current from the power supply 43b to the hot plate 43 is stopped or lowered, the temperature of the hot plate 43 can be lowered at an early time. Therefore, even in case there is a heat input from other than the hot plate 43 during film formation, the substrate Sw can still be controlled to the predetermined temperature.

Description has so far been made of an embodiment of this invention, but this invention shall not be limited to the above embodiment. So long as the substance of this invention is not deviated, various modifications are possible. For example, in the above-mentioned embodiment, description has been made with an example in which the vacuum processing apparatus is defined to be the sputtering apparatus SM. However, as long as there can be disposed in the vacuum processing apparatus, the stage 4 having the thermal insulation plate 44 between the hot plate 43 and the base 41, there is no need of limiting to the above. For example, this invention can be applied, e.g., to the dry etching apparatus, the CVD apparatus and the heat treatment apparatus.

Further, in the above-mentioned embodiment, the chuck plate 42 and the hot plate 43 are constituted as separate constituting elements. However, by housing the heating means inside the chuck plate 42, the chuck plate 42 and the hot plate may be integrally constituted.

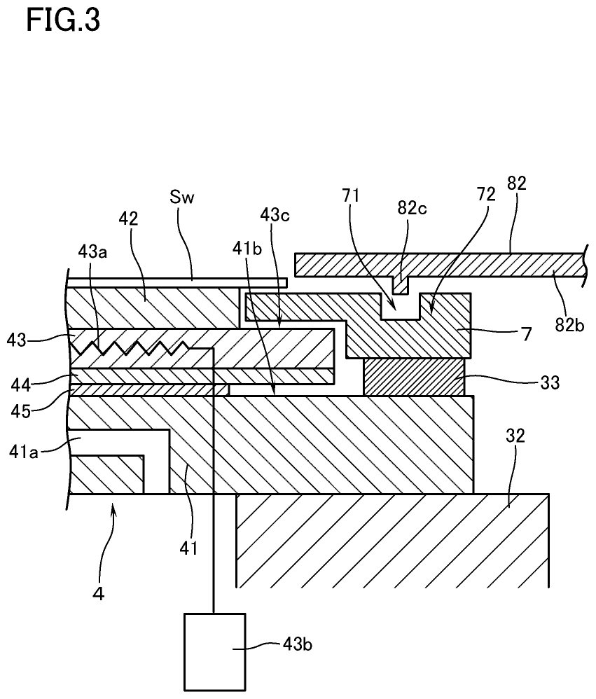

By the way, it is known that the amount of heat-ray emission from the outer peripheral part of the hot plate 43 is larger than that from the central part thereof. If the high-emissivity layer 45 is formed in a manner to cover the entirety of the upper surface of the base 41, the outer peripheral part of the hot plate 43 will become lower in temperature than the central part thereof, thereby giving rise to a temperature difference between the central part and the outer peripheral part of the hot plate 43. Then, there will be a possibility that the vacuum processing cannot be performed uniformly over the entire surface of the substrate Sw. As a solution, as shown in FIG. 3, by forming the high-emissivity layer 45 in a manner to cover such a part of the upper surface of the base as is exclusive of an outer peripheral part 41b on the upper surface of the base 41, the temperature difference that may happen between the central part and the outer peripheral part of the hot plate 43 can advantageously be restrained.

In addition, in the above-mentioned embodiment, description has been made of an example, e.g., of a film given by AlₓTi₁₋ₓN (0.1≤x≤0.95) as a high-emissivity layer 45. However, this invention shall not be limited to the above. By performing surface treatment such as thermal spraying, film forming and the like on the upper surface of the base 41 or on the lower surface of the thermal insulation plate 44, there may be formed a high-emissivity layer composed of a non-metallic film such as of Al₂O₃ and the like or Ti-sprayed film.

### EXPLANATION OF MARKS

SM sputtering apparatus (vacuum processing apparatus)

1 vacuum chamber

4 stage

41 base

42 chuck plate

43 hot plate

44 thermal insulation plate

45 high-emissivity layer, AlₓTi₁₋ₓN film

1. A vacuum processing apparatus comprising:
a vacuum chamber capable of forming vacuum atmosphere;
a stage for supporting inside the vacuum chamber a to-be-processed substrate, the stage having: a base to be selectively cooled; a chuck plate disposed on the base so as to electrostatically absorb the to-be-processed substrate; and a hot plate interposed between the base and the chuck plate, whereby the to-be-processed substrate electrostatically absorbed to a surface of the chuck plate is controlled to a predetermined temperature above a room temperature; and
a thermal insulation plate, disposed between the base and the hot plate, for restraining thermal transmission from the hot plate to the base,
wherein a high-emissivity layer having a higher emissivity than an upper surface of the base is disposed between the base and the thermal insulation plate.

2. The vacuum processing apparatus according to claim 1, wherein the emissivity of the high-emissivity layer is above 0.49.

3. The vacuum processing apparatus according to claim 1, wherein the high-emissivity layer is composed of a film given by AlₓTi₁₋ₓN (0.1≤x≤0.95).

4. The vacuum processing apparatus according to claim 1, wherein the high-emissivity layer is formed in a manner to cover such a part of the upper surface of the base as is exclusive of an outer peripheral part of the upper surface.
